(19) United States
(12) Patent Application Publication
(10) Pub. No.: US 2026/0367533 A1
(43) Pub. Date: Nov. 19, 2026

(54) SYSTEMS AND METHODS FOR MOTION CONTROL OF A PATTERNING DEVICE IN A LITHOGRAPHY APPARATUS

(71) Applicant: ASML NETHERLANDS B.V., Veldhoven (NL)

(72) Inventors: Maarten Hartger KIMMAN, Veldhoven (NL); Marcus Martinus Petrus Adrianus VERMEULEN, Leende (NL); Petrus Franciscus VAN GILS, Riel (NL); Jelmer Mattheüs KAMMINGA, Schijndel (NL)

(73) Assignee: ASML NETHERLANDS B.V., Veldhoven (NL)

(21) Appl. No.: 19/515,447

(22) PCT Filed: Sep. 16, 2024
(86) PCT No.: PCT/EP2024/075784

§ 371 Date: Feb. 27, 2026

Related U.S. Application Data
(60) Provisional application No. 63/539,915, filed on Sep. 22, 2023.

(51) Int. Cl. G03F 7/00

(52) U.S. Cl. CPC G03F 7/70725; G03F 7/707

(57) ABSTRACT

A reticle is typically clamped to a chuck in a lithography apparatus by clamps. The force provided by the clamps may limit how fast the reticle can accelerate (e.g., if the reticle accelerates too quickly, momentum of the reticle may break the clamping force and the reticle may slip on the chuck). A new motion control system is described, which applies a pushing force to the reticle during acceleration, to keep the reticle in its intended position during movement. The system includes a first portion coupled to a short stroke stage of the lithography apparatus and a second portion coupled to a long stroke stage. The first portion is configured to push on the reticle so that it stays in its intended position. The second portion is configured to interact with the first portion to cause the first portion to support the reticle.

### CROSS-REFERENCE TO RELATED APPLICATIONS

This application claims priority of U.S. application 63/539,915 which was filed on 22 Sep. 2023, and which is incorporated herein in its entirety by reference.

### TECHNICAL FIELD

The description herein relates generally to systems and methods for motion control of a patterning device in a lithography apparatus.

### BACKGROUND

A lithography (e.g., projection) apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device.

### SUMMARY

A patterning device such as a reticle is typically clamped to a chuck in a lithography apparatus via a vacuum force (e.g., in a deep ultra violet (DUV) lithography apparatus) or electrostatic pressure (e.g., in an extreme ultra violet (EUV) lithography apparatus). The force provided by the clamps may limit how fast the patterning device can accelerate. For example, if the patterning device accelerates too quickly, acceleration forces on the patterning device may exceed the force with which it is clamped, and the patterning device may slip on the chuck (e.g., momentum of the patterning device may break a friction and/or other force between the patterning device and the chuck). A new motion control system is described, which applies a pushing force to the patterning device during acceleration, to keep the patterning device in its intended position during movement. The system comprises a first portion coupled to a short stroke stage of the lithography apparatus and a second portion coupled to a long stroke stage. The first portion is configured to push on the patterning device so that it stays in its intended position. The second portion is configured to interact with the first portion to cause the first portion to support the patterning device. Advantageously, the first and second portions combine to form a zero stiffness stage, such that disturbance forces from the long stroke stage are not passed to the short stroke stage. In addition, the first and second portions combine to form a Lorentz actuator stage, with a magnet and a coil forming the second portion of the Lorentz actuator stage and being coupled to the long stroke stage, away from the first portion and the pattering device.

According to an embodiment, a motion control system is provided. The motion control system comprises an object holder configured to hold and move an object; a short stroke stage with an actuator configured to cause the object holder to move with relatively shorter strokes (with respect to a long stroke stage); a long stroke stage with an actuator; and a manipulator comprising a first portion coupled to the short stroke stage and a second portion coupled to the long stroke stage. The first portion is configured to support the object held by the object holder to keep the object in an intended position relative to a reference while the object holder moves. The second portion is configured to interact with the first portion to cause the first portion to support the object.

In some embodiments, the reference comprises the object holder.

In some embodiments, supporting the object comprises applying a force against the object to keep the object in the intended position. Applying the force against the object may comprise pushing against the object.

In some embodiments, the second portion interacting with the first portion comprises transmitting forces from the second portion to the first portion such that the first portion pushes against the object.

In some embodiments, the first portion is passive, comprising a pusher with a tip, a pivot, one or more guides, and/or part (e.g., magnets and/or other passive elements) of an actuator. In some embodiments, the manipulator comprises a tuned mass damper configured to suppress any unwanted vibrations coming from the pusher. The one or more guides may comprise a linear guide, an air bearing, a flexure, a hinged flexure, or a combination thereof. The tip may comprise a polymer comprising polyether ether ketone (PEEK), a rubber or rubber like damping material, fluorine kautschuk material (FKM), a perfluoroelastomer (FKKM), Viton™, and/or other materials, for example. The tuned mass damper may comprise a fluoroelastomer and/or other materials, for example.

In some embodiments, the second portion is active, comprising electrical and/or magnetic components including a coil configured to cause the second portion and the first portion to move.

In some embodiments, the first and second portions of the manipulator combine to form a zero stiffness stage, such that disturbance forces from the long stroke stage are not passed to the short stroke stage via the manipulator. In some embodiments, the first and second portions of the manipulator combine to form a Lorentz actuator stage, with a magnet and a coil forming the second portion of the Lorentz actuator stage and being coupled to the long stroke stage, away from the first portion and the object.

In some embodiments, the system comprises one or more processors operatively coupled to the short stroke stage, the long stroke stage, and the manipulator. The one or more processors are configured to provide a feedforward signal to the short stroke stage, the long stroke stage, and the manipulator for the object holder. The feedforward signal is determined based on a desired setpoint trajectory, and/or based on calibrated and/or calculated corrections.

In some embodiments, supporting the object comprises applying a force against the object to keep the object in the intended position with respect to the object holder, and the force comprises purely a feedforward force caused by the manipulator based on the feedforward signal.

In some embodiments, the system comprises a force sensor configured to generate one or more output signals conveying information related to the force applied against the object, the one or more processors further configured to control the short stroke stage, the long stroke stage, and/or the manipulator based on the one or more output signals.

In some embodiments, movement of the object holder comprises acceleration of the object holder.

In some embodiments, the object holder comprises a stage in a semiconductor lithography apparatus, an optical metrology inspection tool, or an e-beam inspection tool. For example, in some embodiments, the object holder comprises a reticle stage chuck or a wafer stage chuck of a lithography apparatus.

In some embodiments, the object comprises a reticle, or a semiconductor wafer, or wafer table.

In some embodiments, the second portion of the manipulator is oriented substantially parallel to a scan direction of the motion control system. In some embodiments, the second portion of the manipulator is oriented substantially perpendicular to a scan direction of the motion control system.

In some embodiments, the second portion of the manipulator comprises a hinge and a pivot configured to translate linear motion of the second portion of the manipulator oriented substantially perpendicular to the scan direction into linear motion substantially parallel to the scan direction.

According to another embodiment, a motion control method is provided. The method is performed by the motion control system, and includes one or more of the operations described above.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts.

FIG. 1 schematically depicts a lithography apparatus, according to an embodiment.

FIG. 2 schematically depicts an embodiment of a lithographic cell or cluster, according to an embodiment.

FIG. 3A illustrates a lithographic apparatus including a reticle handler turret gripper, reticle stage reticle clamps, and/or other components, according to an embodiment.

FIG. 3B is an enlarged view of a portion of the lithographic apparatus shown in FIG. 3A, according to an embodiment.

FIG. 4 illustrates a (transmissive) reticle clamped along the sides of reticle using a vacuum force, according to an embodiment. This is an example associated with a DUV lithography apparatus. As another example, in an EUV lithography apparatus, the reticle is electrostatically clamped via the whole (or nearly whole) backside of the reticle (not only along the sides), though this is not shown in FIG. 4.

FIG. 5A schematically illustrates a patterning device holder in accordance with an embodiment, and some of the forces due to acceleration on the patterning device.

FIG. 5B illustrates a system configured to apply a pushing force (e.g., a pusher) to a reticle (to prevent slipping) during movement, according to an embodiment.

FIG. 6 shows an enlarged side view of a pusher shown in FIGS. 5A and 5B, according to an embodiment.

FIG. 7 shows an example embodiment of an improved (e.g., relative to the system shown in FIGS. 5A, 5B, and 6) motion control system, according to an embodiment.

FIG. 8 shows another example embodiment of an improved motion control system, according to an embodiment.

FIG. 9 shows another example embodiment of an improved motion control system, according to an embodiment.

FIG. 10 shows another example embodiment of an improved motion control system, according to an embodiment.

FIG. 11 illustrates a motion control method, according to an embodiment.

FIG. 12 is a block diagram of an example computer system, according to an embodiment.

### DETAILED DESCRIPTION

In general, an object such as a mask or reticle (e.g., a patterning device) may be a transparent block of material that is covered with a pattern defined by a different, opaque material. Various masks are fed into a lithographic apparatus and used to form layers of a semiconductor device. Clamps (e.g., reticle stage reticle clamps) in the lithographic apparatus are used to secure the masks or reticles during processing. The clamps accelerate in an x and/or y direction, and drive the reticle in a lithographic apparatus scan direction during processing.

A maximum achievable clamping force is limited by the available surface area of clamps, among other factors. This maximum achievable clamping force and the coefficient of friction between reticle clamp surfaces and a reticle determines the maximum acceleration force level (e.g., in a scan direction) that can be used for patterning processes, without the reticle slipping or otherwise moving on the clamps. In some systems, a pushing force is applied to the reticle (to prevent slipping) during acceleration with a high stiffness actuator. In these systems, components that provide the pushing force are entirely located on a short stroke stage of the lithographic apparatus. To avoid disturbances on a reticle caused by a high stiffness actuator during a scan (e.g., exposure in the lithographic apparatus), the actuator retracts a tip (during the scan) that provides the pushing force such that contact with the reticle is broken. This introduces the risk of tip/reticle damage, and dynamic disturbances.

Advantageously, the present systems and methods provide a motion control system with a reticle (or other object) pusher where the reticle is pushed by a pure force zero stiffness, Lorentz, actuator. The zero stiffness nature of the actuator means the pusher can remain in contact with the reticle during acceleration and scanning. The stator of this actuator is located on the long stroke of the dual stroke reticle stage. The guidance of the moving (pushing) part is located on the short stroke stage. Heat dissipation challenges of a zero stiffness, Lorentz, actuator can be avoided by moving the stator (e.g., the heat generating part) of this actuator to the long stroke moving frame or stage as described below, which is achievable with a zero-stiffness design. A zero stiffness design also allows for more compliant parts in the force path of the pusher. This is advantageous for a pusher that is in contact with the reticle during scanning. With this zero stiffness pusher, a “softer” pusher tip can also be chosen, to further reduce or avoid the risk of damaging the reticle. Several options for this motion control system are described herein.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively. In addition, any use of the terms “reticle” or “mask” herein may be considered synonymous with the more general term “patterning device.”

As an introduction, prior to transferring a pattern from a patterning device such as a reticle or mask to a substrate such as a semiconductor wafer, the substrate may undergo various procedures, such as priming, resist coating and a soft bake. After exposure, the substrate may be subjected to other procedures (“post-exposure procedures”), such as a post-exposure bake (PEB), development, a hard bake and measurement and/or other inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing. The individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

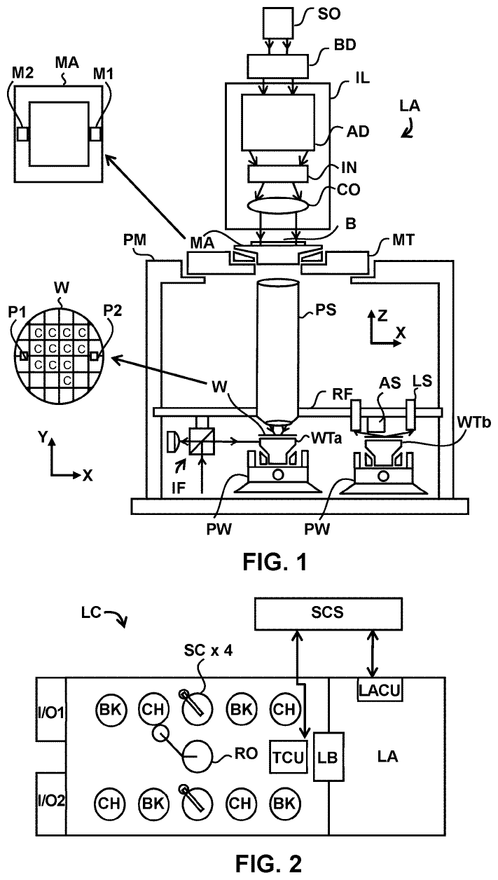

FIG. 1 schematically depicts an embodiment of a lithographic apparatus LA that may be included in and/or associated with the present systems and/or methods. The apparatus comprises: an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. In general, the support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may generally be transmissive or reflective, though transmissive patterning devices are the focus of this particular application. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g., an interferometric device, linear encoder, 2-D encoder, or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In scan mode, the velocity may be non-constant. 3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above. Combinations and/or variations on the above-described modes of use or entirely different modes of use may also be employed.

A substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, critical dimension (CD), edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that other patterns are not defective.

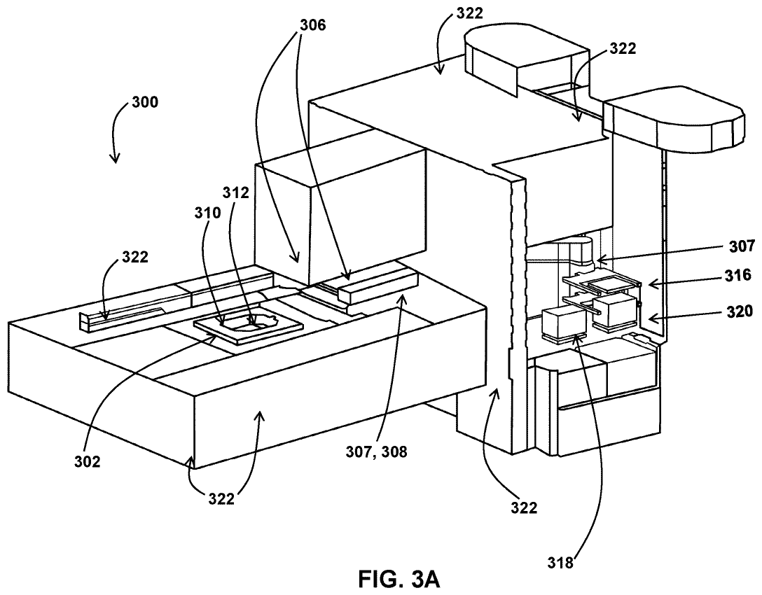

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. For example, contamination on reticle clamp membranes (e.g., as described herein) may adversely affect overlay because clamping a reticle over such contamination will distort the reticle. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

A metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques.

The present systems, and/or methods may be used as stand-alone tools and/or techniques, and/or or used in conjunction with other semiconductor manufacturing processes, to enhance the accurate transfer of complex designs to physical wafers. The present motion control system comprises a clamp configured to apply a clamping force to an object such as a patterning device. The patterning device may be a reticle and/or other patterning devices. The clamp may comprise a reticle clamp for an extreme ultraviolet (EUV) lithography apparatus, a deep ultraviolet (DUV) lithography apparatus, and/or other apparatuses, for example.

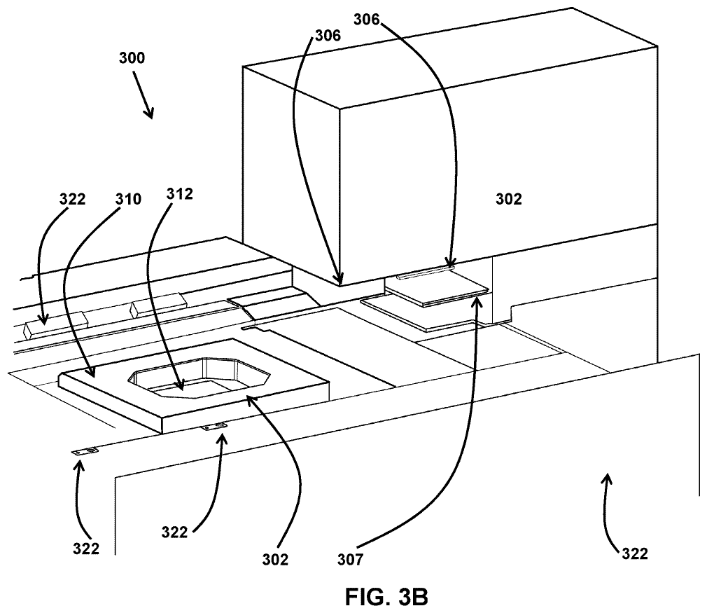

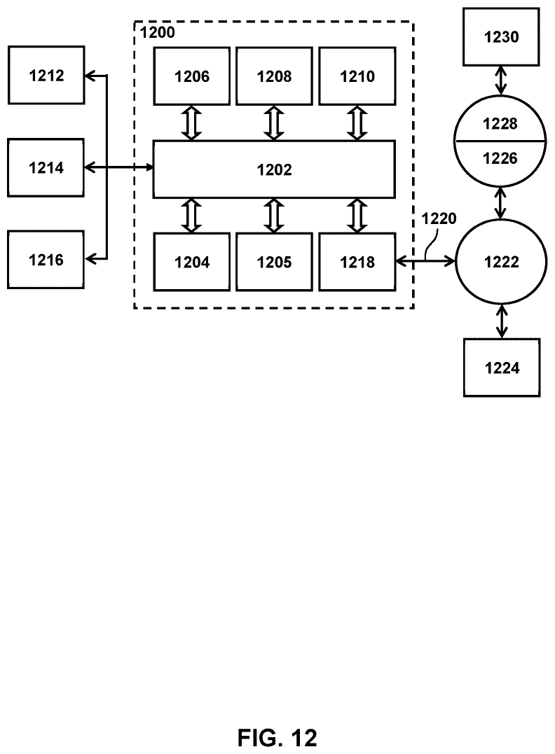

By way of a non-limiting example, FIGS. 3A and 3B illustrate (a portion of) a lithographic apparatus 300 (e.g., similar to an or the same as the lithographic apparatus shown in FIG. 1). Lithographic apparatus 300 may use a patterning device such as a reticle to pattern a substrate such as a semiconductor wafer to form semiconductor devices. FIG. 3A illustrates various components of lithographic apparatus 300 including a tool handler 306, 307, 308, reticle stage 310 and reticle clamps 312 (only one side is visible in FIG. 3A) which form a portion of the present clamping system 302, and/or other components. In some embodiments, lithographic apparatus 300 is configured for deep ultraviolet (DUV) lithography. In some embodiments, a similar apparatus may be configured for extreme ultraviolet (EUV) lithography. In some embodiments, clamping system 302 comprises a reticle stage 310, reticle clamps 312, actuator(s), or more processors and/or computing system described herein (see FIG. 12), one or more sensors, and/or other components. These components are described in turn, below.

In some embodiments, tool handler 306, 307, 308 comprises a reticle handler turret gripper 306, a reticle handler robot gripper 307 (having associated clamps 308, etc. for gripping a reticle), and/or other components. Reticle handler robot gripper 307 may, for example, move a reticle from a pod 320 (e.g., after a user places a reticle in pod 320). Reticle handler turret gripper 306 may, for example, move a reticle from reticle handler robot gripper 307 to reticle clamps 312. Lithographic apparatus 300 may include various other mechanical components 322 (translation mechanisms, elevation mechanisms, rotational mechanisms, motors, power generation and transmission components, structural components, etc.) configured to facilitate movement and control of a reticle through lithographic apparatus 300.

FIG. 3B is an enlarged view of a portion of lithographic apparatus 300. FIG. 3B shows clamping system 302, reticle handler turret gripper 306, reticle stage 310, reticle stage reticle clamps 312 (only one side is visible in FIG. 3B), mechanical components 322, reticle handler robot gripper 307, and/or other components. As shown in FIG. 3B, reticle handler turret gripper 306 is configured to move a reticle from reticle handler robot gripper 307 to reticle clamps 312 so clamping system 302 can be used to clamp the reticle. Moving a reticle may comprise moving the reticle toward or away from the membranes and clamps 312 in horizontal, vertical, and/or other directions. Reticle handler turret gripper 306 and/or reticle handler robot gripper 307 may include various motors, translators, rotational components, clamps, clips, power sources, power transmission components, vacuum mechanisms, and/or other components that facilitate the movement of a reticle.

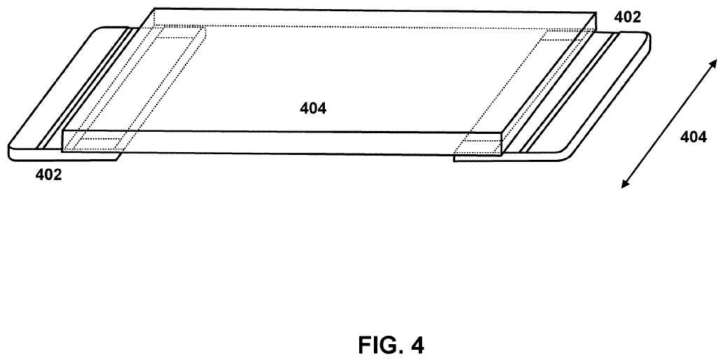

FIG. 4 illustrates a (transmissive) reticle 400 clamped with pads 402 along the sides of reticle 400. In the example shown in FIG. 4, reticle 400 is clamped using a vacuum force. This is an example associated with a DUV lithography apparatus. (Note that in an EUV lithography apparatus, the reticle would be electrostatically clamped via the whole (or nearly whole) backside of the reticle (not only along the sides), though this is not shown in FIG. 4). As described above, the maximum achievable clamping force is limited by the available surface area, among other factors. This maximum achievable clamping force and the coefficient of friction between reticle 400 and pads 402 then determines the maximum acceleration force level (e.g., in scan direction 404) that can be used, without reticle 400 slipping on pads 402. This can be up to about 20 g, for example.

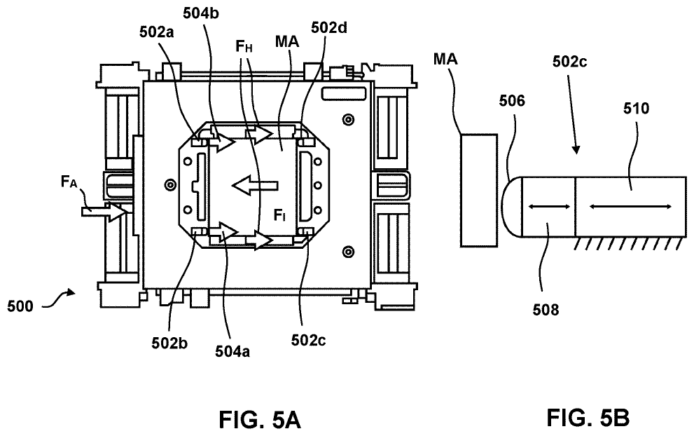

FIG. 5A schematically illustrates a patterning device holder (e.g. a chuck) 500, and some of the forces acting on a patterning device (e.g., patterning device MA shown in FIG. 1) caused by acceleration. FIG. 5A again illustrates a portion of a DUV lithography apparatus (such as the apparatus shown in FIG. 1, FIGS. 3A, and 3B). Similar principles apply for an EUV apparatus. An inertial force F_{I} acts in the direction opposite to the direction of acceleration, or scan direction, of the patterning device MA. This force F_{I} is opposed by a force F_{A} caused by the chuck's vacuum clamping system. To the extent that there is a difference between the inertial force and the chuck holding force, an additional holding or pushing force F_{H} is required to prevent slippage of the patterning device MA. In this example, this additional pushing force is provided by a set of pushers, 502a-d, disposed at corners of the chuck. Because the chuck performs rapid scanning movements primarily in a single direction, four inwardly directed pushers 502a-d are able to provide sufficient stabilizing forces to prevent slippage along the direction of movement of the chuck. Where, as illustrated, the direction of movement is to the right of the figure, the pushers 502a-b will provide respective forces 504a-b opposing F_{I}. When the direction of acceleration is in the opposite direction, the pushers 502c-d will provide the necessary pushing force F_{H}.

FIG. 5B illustrates a system configured to apply a pushing force (e.g., a pusher) to patterning device MA (e.g., a reticle) to prevent slipping during movement, according to an embodiment. FIG. 5b schematically illustrates an example of a pusher 502c in accordance with an embodiment. Though the particular pusher 502c is illustrated, the other pushers 502a, b, d, can be considered to have the same or similar construction. Pusher 502c comprises a tip portion 506 that engages an edge of the patterning device MA as it is held by the patterning device holder along with a fine stroke portion 508 that provides movement at high resolution along its axis. For example, the fine stroke portion may be a piezoelectric actuator designed to provide a single degree of freedom along a range of a few microns (e.g., about 10 μm) with a resolution of about 1 nm. Additionally, pusher 502c is configured to allow for coarse movement (for example by a coarse actuator 510) over a range of a few millimeters (e.g., about 2 mm) with a resolution of about 1 μm.

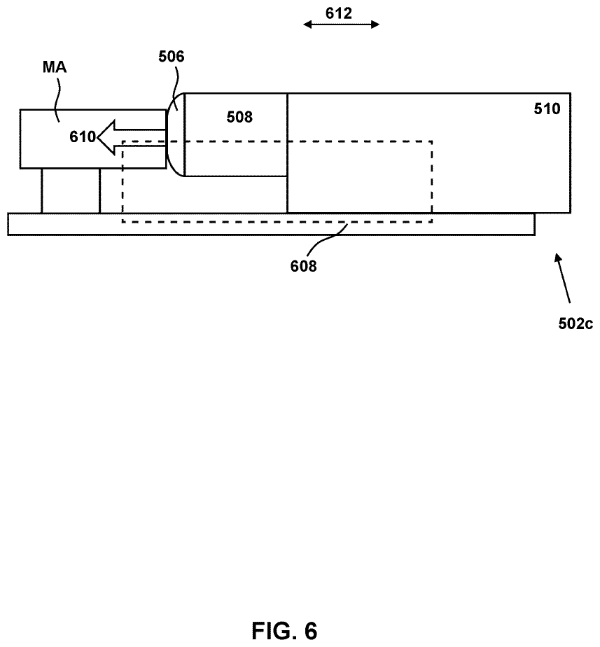

FIG. 6 shows an enlarged side view of pusher 502c shown in FIGS. 5A and 5B. FIG. 6 illustrates a force path 608 associated with the force 610 provided based on the motion 612 of actuator patterning device MA. The stiffnesses in the force path determines the sensitivity (e.g., N/μm) for the extension/position of fine stage 508 and/or position of the coarse stage 510. The force path is important since it shows how the force that is being applied to the patterning device is led through the construction and which individual components contribute to the stiffness. The stiffnesses of the components in the force path impact the applied pushing force. These stiffnesses therefore need to be known (either by calibration or design) and very constant, which can be hard to realize.

The dual stroke nature (e.g., provided via fine stage 508, and a course stage 510) of the system results from two requirements: a stroke requirement for reticle loading, and a low thermal disturbance requirement for the short stroke stage. To create a (relatively high) force while keeping heat dissipation to a minimum, a high stiffness, piezoelectric actuator may be used. With this high stiffness, potential issues related to applying a force feedforward are replaced by potential issues related to position control, and compensating movements with an (assumed) known and/or calibrated stiffness of the actuator. The system shown in FIGS. 5A, 5B, and 6 has several risks and/or drawbacks. For example, this system is dual stroke, with all of the components that provide a pushing force coupled to fine stage 508. Tip 506 is typically a hard tip that goes in and out of contact with patterning device MA (e.g., a reticle) after each scan or exposure in a lithography apparatus which may cause reticle damage and/or particle generation, among other issues. Friction and discontinuities (e.g., tip 506 coming in and out of contact with patterning device MA) are difficult to model and/or otherwise predict. This system is also sensitive to stiffness variations in force path 608 (e.g., through tip 506, fine stage 508, coarse stage 510, etc.).

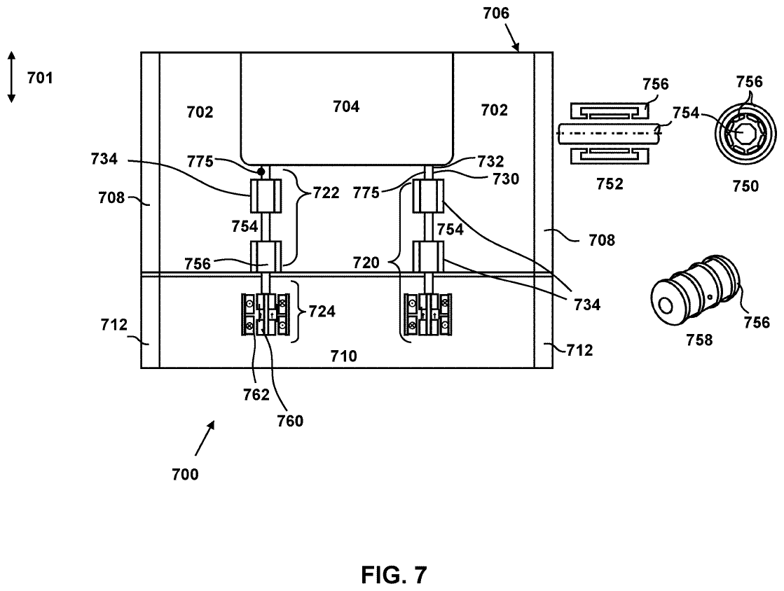

FIG. 7-10 show several example embodiments of an improved (e.g., relative to the system shown in FIGS. 5A, 5B, and 6, and described above) motion control system 700. Note that these are representative examples of many other possible embodiments that may be configured to function as described here. System 700 is configured to apply a pure or nearly pure (feedforward) force to an object such as a reticle, with a zero-stiffness actuator (e.g., a Lorentz actuator). (Note that “zero-stiffness” is a naming convention used herein to indicate a relatively low stiffness compared to other stiffness, and does not necessarily indicate an actuator with no stiffness at all.) Challenges associated with heat dissipation from coils and/or other components of a Lorentz actuator are mitigated and/or avoided altogether by moving the stator (e.g., a second, heat generating, portion of a manipulator described below) of system 700 to a long stroke stage of a lithographic apparatus (such as lithographic apparatus LA shown in FIG. 1), which is possible with a zero-stiffness design.

A zero stiffness design allows for more compliant parts in the force path of a first portion of the manipulator (described below)—with the first portion configured to support an object (such as a reticle) to keep the object in an intended position relative to a reference during movement (e.g., such as acceleration). The first portion may be thought of as, or including, a “pusher”, for example. In system 700 (which has a zero stiffness design), a softer pusher tip (e.g., compared to tip 506 described above) can be used, such as polyetheretherketone (PEEK) and/or other materials (e.g., as described below), minimizing and/or avoiding the risk of damaging the reticle. This is because the tip will remain in contact with the reticle during movement and because of the lower hardness with respect to a glass like material.

FIG. 7 illustrates an example of motion control system 700. System 700 is configured to move in a scan direction 701. System 700 comprises an object holder 702 configured to hold and move an object 704. Movement of object holder 702 may comprise acceleration, constant velocity motion, deceleration, and/or other movement of object holder 702. In some embodiments, object 704 comprises a reticle, a semiconductor wafer, a wafer table, and/or other objects. In the example shown in FIG. 7, object 704 is a reticle (e.g., similar to and/or the same as the reticles and/or patterning devices described above). In some embodiments, object holder 702 comprises a stage in a semiconductor lithography apparatus, an optical metrology inspection tool, or an e-beam inspection tool, and/or other object holders. In some embodiments, object holder 702 comprises a reticle stage chuck or a wafer stage chuck of a lithography apparatus. In the example shown in FIG. 7, object holder 702 is a reticle stage chuck in a semiconductor lithography apparatus.

A reticle stage chuck is used in combination with clamps and/or other components in a lithographic apparatus to secure patterning device or reticle during processing. In some embodiments, system 700 includes and/or is configured to communicate with one or more sensors, one or more processors and/or a computing system as described below (see FIG. 12), and/or other components. The various components of system 700 may be coupled in any arrangement and using any coupling components that allow system 700 to function as described herein.

A clamping force (e.g., vacuum or electrostatic) is applied to a reticle with clamps to clamp the reticle during acceleration and/or other movement. The reticle clamps may be part of a DUV or EUV lithography apparatus, as described above. Acceleration, etc., may be associated with movement of a reticle for a lithography operation.

In some embodiments, a reticle has a rectangular shape. For simplicity and to facilitate the discussion herein, the figures illustrate a reticle as a single block of material shaped as a rectangular prism. In some embodiments, some or all of a reticle may be formed from an opaque, transparent, or nearly transparent material such as ultra-low thermal-expansion quartz (SFS), a transparent material such as glass, an opaque material such as metal, a polymer, a ceramic, and/or other materials. Fabrication of a reticle can utilize any number of materials.

System 700 comprises a short stroke stage 706 with an actuator 708 (two example schematic actuators 708 are shown in FIG. 7) configured to cause object holder 702 to move with relatively shorter strokes. System 700 comprises a long stroke stage 710 with an actuator 712 (two example schematic actuators 712 are shown in FIG. 7) configured to follow short stroke stage 706 with relatively longer strokes in comparison with short stroke stage 706. System 700 comprises a manipulator 720 (two examples of manipulator 720 are shown in FIG. 7) comprising a first portion 722 coupled to short stroke stage 706 and a second portion 724 coupled to long stroke stage 710. First and second portions 722 and 724 of manipulator 720 combine to form a zero stiffness stage (e.g., in scan direction 701), such that disturbance forces from long stroke stage 710 are not passed to short stroke stage 706 via the manipulator. In some embodiments, the first and second portions 722 and 724 of manipulator 720 combine to form a Lorentz actuator stage, with a magnet and a coil forming the second portion of the Lorentz actuator stage and being coupled to the long stroke stage, away from the first portion and the object (e.g., as described below).

First portion 722 is configured to support object 704 held by object holder 702 to keep object 704 in an intended position relative to a reference while object holder 702 moves. In some embodiments, the reference comprises object holder 702, and/or some other component of and/or associated with a lithographic apparatus (such as lithographic apparatus LA described above). Supporting object 704 may comprise applying a force against object 704 to keep object 704 in the intended position, and/or other operations. Applying the force against object 704 may comprise pushing against object 704, for example. Second portion 724 is configured to interact with first portion 722 to cause first portion 722 to support object 704. Interacting with first portion 722 comprises transmitting forces from second portion 724 to first portion 722 such that first portion 722 pushes against object 704, for example.

In some embodiments, first portion 722 is passive, comprising a pusher 730 with a tip 732 (only one example of each of these, and similarly other components, are labeled in FIG. 7 for labelling space reasons, but two or more of each of these are shown), a pivot (e.g., as described below), one or more guides 734, an actuator (as described herein), and/or other components. In FIG. 7, pusher 730 and tip 732 are shown retracted (from object 704 and/or object holder 702) by about 5 mm to facilitate reticle (e.g., the object in this example) loading into object holder 702. Tip 732 may comprise a polymer such as polyether ether ketone (PEEK), a rubber or rubber like damping material, fluorine kautschuk material (FKM), a perfluoroelastomer (FKKM), Viton™, and/or other materials. The one or more guides 734 may comprise a linear guide, an air bearing, a flexure, a hinged flexure, a combination thereof, and/or other guides. In the example shown in FIG. 7, pusher 730 is formed by a shaft, and one or more guides 734 comprise air bearings. FIG. 7 illustrates an example end view 750 and an example side view 752 of a shaft 754 passing through an air bearing 756. A perspective view 758 of an example air bearing 756 is also shown. In some embodiments, first portion 722 of manipulator 720 is oriented substantially parallel to scan direction 701 of motion control system 700, as shown in FIG. 7. However, in some embodiments, first portion 722 may be oriented substantially perpendicular to scan direction 701.

In some embodiments, second portion 724 is active, comprising electrical and/or magnetic components including magnets 760, a coil 762, and/or other components configured to cause second portion 724 (including one or more components thereof), and in turn first portion 722, to move. Advantageously, this keeps coils 762 and/or other components which may generate heat away from short stroke stage 706. This may facilitate better and/or less potentially problematic heat dissipation from these components of system 700. In some embodiments, a guide 734 is coupled to the chuck (short stroke), components 732, 730, 775, 754 and 760 form one part (e.g., a pusher), and (only) coil 762 is coupled to the long stroke (e.g., not the complete 724 portion).

In some embodiments, first portion 722, second portion 724, and/or other portions of manipulator 720 comprise a tuned mass damper configured to suppress any unwanted vibrations coming from pusher 730 and/or other components of system 700. The mass of the Lorentz actuator magnets and the stiffness of the tip results in a resonant system. Vibrations from this resonating system may or may not disturb the object/or mask in an unwanted manner. A second, damped, resonating system can be added to the mover, e.g. at the end of the rod on the actuator magnet. This way, a tuned mass damper is created to suppress any unwanted disturbances. The tuned mass damper may comprise a fluoroelastomer, for example, and/or other materials. In FIG. 7, the shaft's mass together with the pusher tip's stiffness and damping form a tuned mass damper in scan direction 701. The shaft's mass together with the stiffness of the bearings 756 form a tuned mass damper perpendicular to scan direction 701. Note that a tuned mass damper could be added at the end of the rod at which the magnets of the actuator are attached. Other embodiments are contemplated.

Like first portion 722, in some embodiments, second portion 724 of manipulator 720 is oriented substantially parallel to scan direction 701 of motion control system 700, as shown in FIG. 7. However, in some embodiments, second portion 724 may be oriented substantially perpendicular to scan direction 701. The various components of system 700 may be coupled to each other as shown in FIG. 7 by screws, nuts, bolts, clips, clamps, adhesive, and/or any other coupling mechanism that allows each component to function as described herein.

In some embodiments, system 700 comprises one or more processors and/or a computing system, as described below (see FIG. 12). The one or more processors and/or computing system may be operatively coupled to short stroke stage 706, long stroke stage 710, a manipulator 720, and/or other components. The one or more processors and/or computing system may be configured to provide a feedforward signal to short stroke stage 706, long stroke stage 710, and/or manipulator 720 for object holder 702. The feedforward signal may be determined based on a desired setpoint trajectory, based on calibrated and/or calculated corrections, and/or other information. The setpoint trajectory is the movement profile (position/velocity/acceleration/jerk/etc.) that the stage 706 should follow. The setpoint trajectory describes the position in time the stage should follow to perform an exposure, for example, as described above, in the context of the scanning mode. A corresponding velocity and acceleration setpoint may be associated with a desired position setpoint. Depending on the physics of a given situation, either one of these trajectories can be used to apply a feed forward signal to improve the tracking of the position setpoint. Corrections may comprise small deviations from this ideal trajectory to correct for imperfections in an exposure (e.g. a heated lens or an external disturbance, etc.). Calibrated/calculated corrections may be needed to deal with imperfections of the stage and/or disturbance forces acting on the stage. This data may be entered and/or selected by a user via a user interface that is part of the computing system (see FIG. 12), determined automatically by the one or more processors, and/or obtained by other methods. In some embodiments, supporting object 704 (e.g., a reticle) comprises applying a force against object 704 to keep object 704 in the intended position with respect to object holder 702 (e.g., as described above). The force may comprise purely a feedforward force caused by manipulator 720 (e.g., controlled by the one or more processors) based on the feedforward signal. In some embodiments, system 700 comprises a force sensor 775 configured to generate one or more output signals conveying information related to the force applied against object 704. The one or more processors may be configured to control short stroke stage 706, long stroke stage 710, manipulator 720, and/or other components of system 700 based on the one or more output signals to function as described herein.

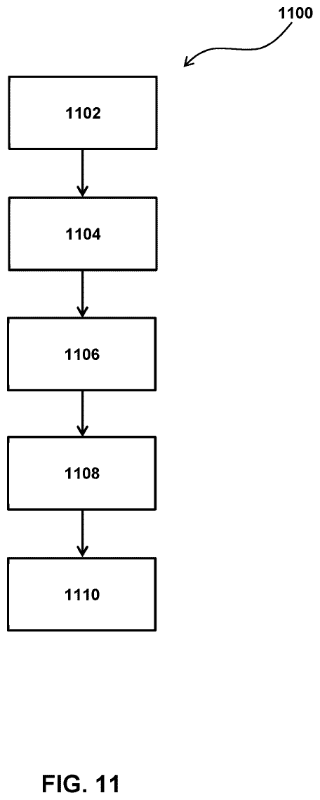

For example, in some embodiments, one or more processors (see FIG. 11) are operatively coupled to actuator 702 and configured to determine that a reticle (e.g., object 704) is clamped and/or about to move. Responsive to such a determination, the one or more processors may cause pusher 730 to apply force to the reticle. One or more sensors included in a lithography apparatus (e.g., in addition to one or more sensors 775) may generate output signals conveying information related to the movement of the reticle. The one or more sensors may comprise one or more accelerometers, for example, and/or other sensors. The one or more processors may be configured to determine that a reticle is moving and/or about to move based on the output signals and/or other information. In some embodiments, the one or more processors may determine that a reticle is moving and/or about to move based on an instruction and/or command provided by and/or otherwise associated with a lithography apparatus, and/or other information.

In some embodiments, the one or more processors and/or the one or more sensors may be included in lithographic apparatus LA and/or lithographic apparatus 300 (FIGS. 3A, 3B), for example, and/or be associated with control software running on lithographic apparatus 300. The one or more processors are configured by machine-readable instructions. Communication may be wired and/or wireless, for example, as described below (in conjunction with FIG. 12). One or more processors may facilitate receiving entry and/or selection of control commands from the user via a user interface. In some embodiments, the one or more processors may determine the control commands automatically. These control commands may be received in real time or near real time. In some embodiments, the control commands comprise adjustments to a scan movement profile, for example, forces provided by system 700, feedforward signals, and/or other control commands.

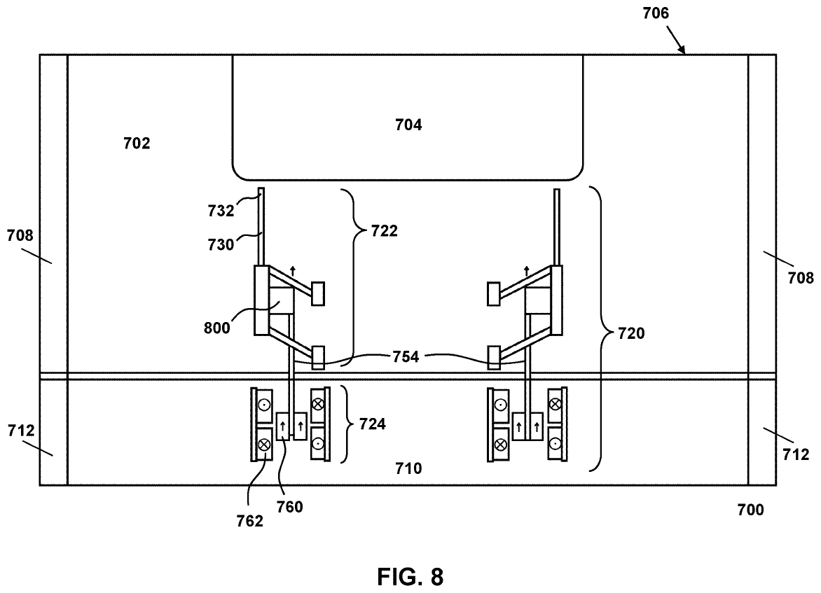

FIG. 8 shows another example embodiment of motion control system 700. In the embodiment of system 700 shown in FIG. 8, a direct drive flexure 800 is included in manipulator 720 (two example manipulators 720 with two example direct drive flexures 800 are shown in FIG. 8, though only one set of components is labeled in FIG. 8 for labelling space clarity reasons). Direct drive flexure 800 is provided on the chuck body (e.g., object holder 702). Direct drive flexure 800 may function as a guide for pusher 730, and/or perform other operations. Direct drive flexure 800 may provide a faster response, higher stiffness, and less friction; may require less maintenance and/or provide better straightness and flatness of motion compared to mechanical guiding mechanisms.

A direct drive flexure can be made flexible in the scan direction (701) and stiff in the others. This can solve dynamic issues perpendicular to 701. Additionally, a direct drive flexure does not have hysteresis in scan direction 701. Further, a direct drive concept does not have a transmission in between the motor and the reticle, so the motor has to deliver the required acceleration force 1:1 (a transmission could reduce that required force). Linear guides have the advantage of not needing an air supply, no friction, and being a monolithic structure, which is less sensitive to tolerances and indeed maintenance (wear). Direct drive flexures 800 may be coupled to the chuck body, to other components of a manipulator 720, and/or other components of system 700, by screws, nuts, bolts, clips, clamps, adhesive, and/or any other coupling mechanism that allows direct drive flexures 800 and/or manipulator 720 to function as described herein.

With the direct drive concept, an actuator mover needs to be accelerated (e.g., at 30 g) by the actuator itself. However, by introducing a hinge, the actuator mover mass can aid in pushing. This significantly reduces the actuator load, and thus the actuator mass and volume. The actuator mover mass largely determines the dynamic performance of the flexure assembly in contact with the reticle during exposure. The actuator mass therefore is configured to be kept as low as possible.

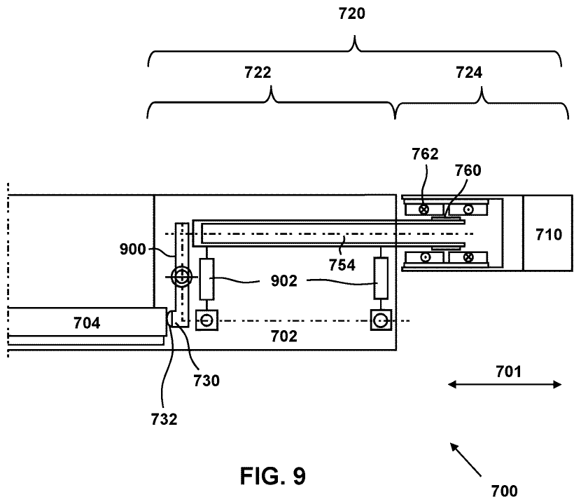

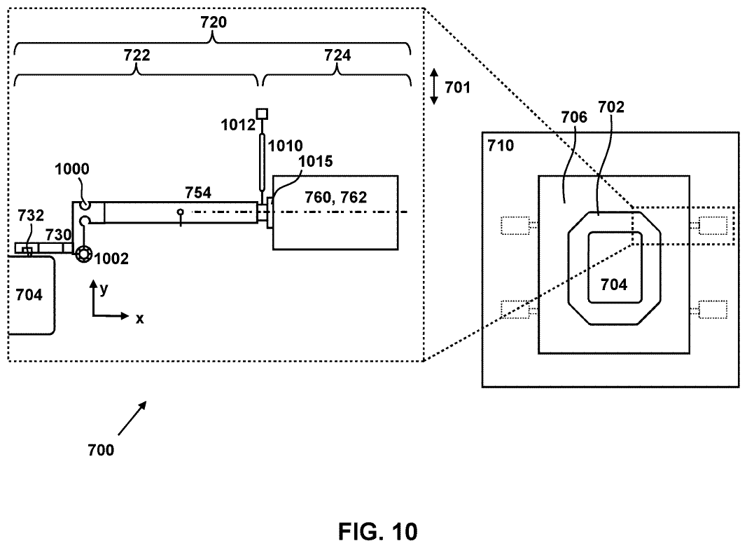

FIG. 9 and FIG. 10 illustrate more example embodiments of motion control system 700. FIG. 9 and FIG. 10 illustrate two embodiments of a hinged flexure guidance on the chuck body (e.g., object holder 702) that include an in line embodiment (e.g., a “hinged Y-pusher”, shown in FIG. 9) and a 90° embodiment (“hinged X-pusher”, shown in FIG. 10). In FIG. 9, pusher 730 (e.g., the first portion 722 of manipulator 720 in this example) is centered on a pivot point 900 such that when shaft 754 is actuated by magnets 760 and coil 762 (e.g., the second portion 724 of manipulator 720 in this example), tip 732 pushes on object 704(a reticle in this example). FIG. 9 also illustrates flexures 902 (which may also be termed elastic guiding elements, leaf springs, etc.) positioned on the chuck body (e.g., object holder 702). The flexures are coupled to the shaft with low stiffness in scan direction 701. This may be accomplished by welding, gluing, and/or other coupling operations. The flexures can be manufactured as monolithic part.

As shown in FIG. 10, in the hinged X-pusher, actuator/mover (e.g., see 760, 762) inertia is compensated by the stiff direction of the flexures (as described below, flexure 1010 with ground 1012 is stiff in the y-direction and has low stiffness in the x-direction). In this embodiment, second portion 724 of manipulator 720 is oriented substantially perpendicular to a scan direction 701 of system 700. This embodiment of manipulator 720 comprises a hinge 1000 and a pivot 1002 configured to translate linear motion of second portion 724 of manipulator 720 oriented substantially perpendicular to scan direction 701 into linear motion substantially parallel to scan direction 701. In this example, hinge 1000 is a titanium live hinge, but other possible hinges are contemplated. Pivot 1002 can be a roller bearing, a flexible rotational element, a flux pivot, and/or other pivots. Pivot 1002 is grounded (e.g., connected and/or mounted) to the chuck body (e.g., object holder 702). Shaft 754 is an aluminum tube in this embodiment, but other shafts and/or shaft materials are possible. Flexure 1010 may be a (e.g., titanium) leaf spring, for example, and/or other flexures. Flexure 1010 may be grounded 1012 to the chuck. This embodiment may include an (e.g., aluminum) spacer 1015 and/or other components necessary to function as described herein. Flexure based embodiments, (e.g., see FIG. 10 and FIG. 9) can be extended with an additional negative stiffness to compensate for the positive flexure stiffness. This can be in the form of a buckled leaf spring, and/or other components, for example.

FIG. 11 illustrates a motion control method 1100. Method 1100 may be performed with a motion control system, as described above, for example. In some embodiments, the motion control system includes and/or is configured to communicate with one or more processors and/or a computing system, as described below (see FIG. 12). The operations of method 1100 presented below are intended to be illustrative. In some embodiments, method 1100 may be accomplished with one or more additional operations not described, and/or without one or more of the operations discussed. Additionally, the order in which the operations of method 1100 are illustrated in FIG. 11 and described below is not intended to be limiting. For example, one or more of these operations may not occur sequentially in time, but instead in parallel.

In some embodiments, one or more portions of method 1100 may be implemented in and/or controlled by one or more processing devices (e.g., a digital processor, an analog processor, a digital circuit designed to process information, an analog circuit designed to process information, a state machine, and/or other mechanisms for electronically processing information, as described with respect to FIG. 12 below). The one or more processing devices may include one or more devices executing some or all of the operations of method 1100 in response to instructions stored electronically on an electronic storage medium. The one or more processing devices may include one or more devices configured through hardware, firmware, and/or software to be specifically designed for execution of one or more of the operations of method 1100 (e.g., see discussion related to FIG. 12 below).

At an operation 1102, an object may be held and moved with an object holder. In some embodiments, the object holder comprises a stage in a semiconductor lithography apparatus, an optical metrology inspection tool, or an e-beam inspection tool, and/or other objects. In some embodiments, the object holder may comprise a reticle stage chuck or a wafer stage chuck of a lithography apparatus, and/or other object holders. The object may comprise a patterning device such as a reticle, a semiconductor wafer, a wafer table, and/or other objects, for example. Movement of the object holder may comprise acceleration of the object holder, and/or other movement. In some embodiments, one or more of the stages and/or chucks described above may be associated with a lithography apparatus configured for DUV or EUV radiation. In some embodiments, operation 1102 is performed by an object holder similar to and/or the same as object holder 702 shown in FIG. 7 and described herein, and/or other components.

Operation 1104 comprises causing, with a short stroke stage having an actuator, the object holder to move with relatively shorter strokes. In some embodiments, operation 1104 is performed by a short stroke stage similar to and/or the same as short stroke stage 706 shown in FIG. 7 and described herein, and/or other components. Operation 1106 comprises following, with a long stroke stage having an actuator, the short stroke stage with relatively longer strokes in comparison with the short stroke stage. In some embodiments, operation 1106 is performed by a long stroke stage similar to and/or the same as long stroke stage 710 shown in FIG. 7 and described herein, and/or other components.

Operation 1108 comprises supporting, with a first portion of a manipulator that is coupled to the short stroke stage, the object held by the object holder to keep the object in an intended position relative to a reference while the object holder moves. Supporting the object comprises applying a force against the object to keep the object in the intended position. Applying the force against the object comprises pushing against the object, and/or other applications of force. The reference may be the object holder, and/or other references.

In some embodiments, the first portion is passive, comprising a pusher with a tip, a pivot, one or more guides, an actuator, and/or other components. In some embodiments, the manipulator comprises a tuned mass damper configured to suppress any unwanted vibrations coming from the pusher. The one or more guides may comprise a linear guide, an air bearing, a flexure, a hinged flexure, and/or other guides. The tip comprises a polymer comprising polyether ether ketone (PEEK), a rubber or rubber like damping material, fluorine kautschuk material (FKM), a perfluoroelastomer (FKKM), Viton™, and/or other materials. In some embodiments, the tuned mass damper may comprise a fluoroelastomer, and/or other materials. In some embodiments, operation 1208 is performed by a manipulator similar to and/or the same as manipulator 720 shown in FIG. 7 and described herein, and/or other components.

Operation 1110 comprises interacting, with a second portion of the manipulator coupled to the long stroke stage, with the first portion to cause the first portion to support the object. The second portion interacting with the first portion comprises transmitting forces from the second portion to the first portion such that the first portion pushes against the object. In some embodiments, the second portion is active, comprising electrical and/or magnetic components including a coil configured to cause the second portion and the first portion to move. In some embodiments, the second portion of the manipulator is oriented substantially parallel to a scan direction of the motion control system. In some embodiments, the second portion of the manipulator is oriented substantially perpendicular to a scan direction of the motion control system. In some embodiments, the second portion of the manipulator comprises a hinge a pivot, and/or other components configured to translate linear motion of the second portion of the manipulator oriented substantially perpendicular to the scan direction into linear motion substantially parallel to the scan direction. In some embodiments, operation 1110 is performed by a manipulator similar to and/or the same as manipulator 720 shown in FIG. 7 and described herein, and/or other components.

In some embodiments, the first and second portions of the manipulator combine to form a zero stiffness stage, such that disturbance forces from the long stroke stage are not passed to the short stroke stage via the manipulator. In some embodiments, the first and second portions of the manipulator combine to form a Lorentz actuator stage, with a magnet and a coil forming the second portion of the Lorentz actuator stage and being coupled to the long stroke stage, away from the first portion and the object.

In some embodiments, method 1100 comprises providing, with one or more processors operatively coupled to the short stroke stage, the long stroke stage, the manipulator, and/or other components, a feedforward signal to the short stroke stage, the long stroke stage, and the manipulator for the object holder. The feedforward signal is determined based on a desired setpoint trajectory, based on calibrated and/or calculated corrections, and/or other information. In some embodiments, supporting the object comprises applying a force against the object to keep the object in the intended position with respect to the object holder, and the force comprises purely a feedforward force caused by the manipulator based on the feedforward signal.

In some embodiments, method 1100 comprises generating, with a force sensor, one or more output signals conveying information related to the force applied against the object, and controlling, with the one or more processors, the short stroke stage, the long stroke stage, and/or the manipulator based on the one or more output signals.

FIG. 12 is a block diagram that illustrates a computer system 1200 that can assist in implementing the methods, flows, or the system(s) disclosed herein. Computer system 1200 includes a bus 1202 or other communication mechanism for communicating information, and a processor 1204 (or multiple processors 1204 and 1205) coupled with bus 1202 for processing information. Computer system 1200 also includes a main memory 1206, such as a random access memory (RAM) or other dynamic storage device, coupled to bus 1202 for storing information and instructions to be executed by processor 1204. Main memory 1206 also may be used for storing temporary variables or other intermediate information during execution of instructions to be executed by processor 1204. Computer system 1200 further includes a read only memory (ROM) 1208 or other static storage device coupled to bus 1202 for storing static information and instructions for processor 1204. A storage device 1210, such as a magnetic disk or optical disk, is provided and coupled to bus 1202 for storing information and instructions.

Computer system 1200 may be coupled via bus 1202 to a display 1212, such as a cathode ray tube (CRT) or flat panel or touch panel display for displaying information to a computer user. An input device 1214, including alphanumeric and other keys, is coupled to bus 1202 for communicating information and command selections to processor 1204. Another type of user input device is cursor control 1216, such as a mouse, a trackball, or cursor direction keys for communicating direction information and command selections to processor 1204 and for controlling cursor movement on display 1212. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more flows and/or methods described herein may be performed by computer system 1200 in response to processor 1204 executing one or more sequences of one or more instructions contained in main memory 1206. Such instructions may be read into main memory 1206 from another computer-readable medium, such as storage device 1210. Execution of the sequences of instructions contained in main memory 1206 causes processor 1204 to perform the flows and/or process steps described herein. One or more processors in a multi-processing arrangement may also be employed to execute the sequences of instructions contained in main memory 1206. In an alternative embodiment, hard-wired circuitry may be used in place of or in combination with software instructions. Thus, the description herein is not limited to any specific combination of hardware circuitry and software.

The term “computer-readable medium” or “machine readable medium” as used herein refers to any medium that participates in providing instructions to processor 1204 for execution. Such a medium may take many forms, including but not limited to, non-volatile media, volatile media, and transmission media. Non-volatile media include, for example, optical or magnetic disks, such as storage device 1210. Volatile media include dynamic memory, such as main memory 1206. Transmission media include coaxial cables, copper wire and fiber optics, including the wires that comprise bus 1202. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1204 for execution. For example, the instructions may initially be borne on a magnetic disk of a remote computer. The remote computer can load the instructions into its dynamic memory and send the instructions over a telephone line using a modem. A modem local to computer system 1200 can receive the data on the telephone line and use an infrared transmitter to convert the data to an infrared signal. An infrared detector coupled to bus 1202 can receive the data carried in the infrared signal and place the data on bus 1202. Bus 1202 carries the data to main memory 1206, from which processor 1204 retrieves and executes the instructions. The instructions received by main memory 1206 may optionally be stored on storage device 1210 either before or after execution by processor 1204.

Computer system 1200 may also include a communication interface 1218 coupled to bus 1202. Communication interface 1218 provides a two-way data communication coupling to a network link 1220 that is connected to a local network 1222. For example, communication interface 1218 may be an integrated services digital network (ISDN) card or a modem to provide a data communication connection to a corresponding type of telephone line. As another example, communication interface 1218 may be a local area network (LAN) card to provide a data communication connection to a compatible LAN. Wireless links may also be implemented. In any such implementation, communication interface 1218 sends and receives electrical, electromagnetic, or optical signals that carry digital data streams representing various types of information.

Network link 1220 typically provides data communication through one or more networks to other data devices. For example, network link 1220 may provide a connection through local network 1222 to a host computer 1224 or to data equipment operated by an Internet Service Provider (ISP) 1226. ISP 1226 in turn provides data communication services through the worldwide packet data communication network, now commonly referred to as the “Internet” 1228. Local network 1222 and Internet 1228 both use electrical, electromagnetic, or optical signals that carry digital data streams. The signals through the various networks and the signals on network link 1220 and through communication interface 1218, which carry the digital data to and from computer system 1200, are exemplary forms of carrier waves transporting the information.

Computer system 1200 can send messages and receive data, including program code, through the network(s), network link 1220, and communication interface 1218. In the Internet example, a server 1230 might transmit a requested code for an application program through Internet 1228, ISP 1226, local network 1222 and communication interface 1218. One such downloaded application may provide all or part of a method described herein, for example. The received code may be executed by processor 1204 as it is received, and/or stored in storage device 1210, or other non-volatile storage for later execution. In this manner, computer system 1200 may obtain application code in the form of a carrier wave.

Various embodiments of the present systems and methods are disclosed in the subsequent list of numbered clauses:
1. A motion control system, comprising: an object holder configured to hold and move an object; a short stroke stage with an actuator configured to cause the object holder to move with relatively shorter strokes; a long stroke stage with an actuator; and a manipulator comprising a first portion coupled to the short stroke stage and a second portion coupled to the long stroke stage, wherein: the first portion is configured to support the object held by the object holder to keep the object in an intended position relative to a reference while the object holder moves, and the second portion is configured to interact with the first portion to cause the first portion to support the object.
2. The system of clause 1, wherein the reference comprises the object holder.
3. The system of any of the previous clauses, wherein supporting the object comprises applying a force against the object to keep the object in the intended position.
4. The system of any of the previous clauses, wherein applying the force against the object comprises pushing against the object.
5. The system of any of the previous clauses, wherein the second portion interacting with the first portion comprises transmitting forces from the second portion to the first portion such that the first portion pushes against the object.
6. The system of any of the previous clauses, wherein the first portion is passive, comprising a pusher with a tip, a pivot, one or more guides, and/or part of an actuator.
7. The system of any of the previous clauses, wherein the manipulator comprises a tuned mass damper configured to suppress any unwanted vibrations coming from the pusher.
8. The system of any of the previous clauses, wherein the one or more guides comprise a linear guide, an air bearing, a flexure, a hinged flexure, or a combination thereof.
9. The system of any of the previous clauses, wherein the tip comprises a polymer comprising polyether ether ketone (PEEK), a rubber or rubber like damping material, fluorine kautschuk material (FKM), a perfluoroelastomer (FKKM), and/or Viton™.
10. The system of any of the previous clauses, wherein the second portion is active, comprising electrical and/or magnetic components including a coil configured to cause the second portion and the first portion to move.
11. The system of any of the previous clauses, wherein the first and second portions of the manipulator combine to form a zero stiffness stage, such that disturbance forces from the long stroke stage are not passed to the short stroke stage via the manipulator.
12. The system of any of the previous clauses, wherein the first and second portions of the manipulator combine to form a Lorentz actuator stage, with a magnet and a coil forming the second portion of the Lorentz actuator stage and being coupled to the long stroke stage, away from the first portion and the object.
13. The system of any of the previous clauses, further comprising one or more processors operatively coupled to the short stroke stage, the long stroke stage, and the manipulator, the one or more processors configured to provide a feedforward signal to the short stroke stage, the long stroke stage, and the manipulator for the object holder, the feedforward signal determined based on a desired setpoint trajectory, and/or based on calibrated and/or calculated corrections.
14. The system of any of the previous clauses, wherein supporting the object comprises applying a force against the object to keep the object in the intended position with respect to the object holder, and the force comprises purely a feedforward force caused by the manipulator based on the feedforward signal.
15. The system of any of the previous clauses, further comprising a force sensor configured to generate one or more output signals conveying information related to the force applied against the object, the one or more processors further configured to control the short stroke stage, the long stroke stage, and/or the manipulator based on the one or more output signals.
16. The system of any of the previous clauses, wherein movement of the object holder comprises acceleration of the object holder.
17. The system of any of the previous clauses, wherein the object holder comprises a stage in a semiconductor lithography apparatus, an optical metrology inspection tool, or an e-beam inspection tool.
18. The system of any of the previous clauses, wherein the object holder comprises a reticle stage chuck or a wafer stage chuck of a lithography apparatus.
19. The system of any of the previous clauses, wherein the object comprises a reticle or a semiconductor wafer, or wafer table.
20. The system of any of the previous clauses, wherein the second portion of the manipulator is oriented substantially parallel to a scan direction of the motion control system.
21. The system of any of the previous clauses, wherein the second portion of the manipulator is oriented substantially perpendicular to a scan direction of the motion control system.
22. The system of any of the previous clauses, wherein the second portion of the manipulator comprises a hinge and a pivot configured to translate linear motion of the second portion of the manipulator oriented substantially perpendicular to the scan direction into linear motion substantially parallel to the scan direction.
23. A motion control method, comprising: holding and moving an object with an object holder; causing, with a short stroke stage having an actuator, the object holder to move with relatively shorter strokes; following, with a long stroke stage having an actuator; supporting, with a first portion of a manipulator that is coupled to the short stroke stage, the object held by the object holder to keep the object in an intended position relative to a reference while the object holder moves, and interacting, with a second portion of the manipulator coupled to the long stroke stage, with the first portion to cause the first portion to support the object.
24. The method of clause 23, wherein the reference comprises the object holder.
25. The method of any of the previous clauses, wherein supporting the object comprises applying a force against the object to keep the object in the intended position.
26. The method of any of the previous clauses, wherein applying the force against the object comprises pushing against the object.
27. The method of any of the previous clauses wherein the second portion interacting with the first portion comprises transmitting forces from the second portion to the first portion such that the first portion pushes against the object.
28. The method of any of the previous clauses, wherein the first portion is passive, comprising a pusher with a tip, a pivot, one or more guides, and/or part of an actuator.
29. The method of any of the previous clauses, wherein the manipulator comprises a tuned mass damper configured to suppress any unwanted vibrations coming from the pusher.
30. The method of any of the previous clauses, wherein the one or more guides comprise a linear guide, an air bearing, a flexure, a hinged flexure, or a combination thereof.
31. The method of any of the previous clauses, wherein the tip comprises a polymer comprising polyether ether ketone (PEEK), a rubber or rubber like damping material, fluorine kautschuk material (FKM), a perfluoroelastomer (FKKM), and/or Viton™.
32. The method of any of the previous clauses, wherein the second portion is active, comprising electrical and/or magnetic components including a coil configured to cause the second portion and the first portion to move.
33. The method of any of the previous clauses, wherein the first and second portions of the manipulator combine to form a zero stiffness stage, such that disturbance forces from the long stroke stage are not passed to the short stroke stage via the manipulator.
34. The method of any of the previous clauses, wherein the first and second portions of the manipulator combine to form a Lorentz actuator stage, with a magnet and a coil forming the second portion of the Lorentz actuator stage and being coupled to the long stroke stage, away from the first portion and the object.
35. The method of any of the previous clauses, further comprising providing, with one or more processors operatively coupled to the short stroke stage, the long stroke stage, and the manipulator, a feedforward signal to the short stroke stage, the long stroke stage, and the manipulator for the object holder, the feedforward signal determined based on a desired setpoint trajectory, and/or based on calibrated and/or calculated corrections.
36. The method of any of the previous clauses, wherein supporting the object comprises applying a force against the object to keep the object in the intended position with respect to the object holder, and the force comprises purely a feedforward force caused by the manipulator based on the feedforward signal.
37. The method of any of the previous clauses, further comprising generating, with a force sensor, one or more output signals conveying information related to the force applied against the object, and controlling, with the one or more processors, the short stroke stage, the long stroke stage, and/or the manipulator based on the one or more output signals.
38. The method of any of the previous clauses, wherein movement of the object holder comprises acceleration of the object holder.
39. The method of any of the previous clauses, wherein the object holder comprises a stage in a semiconductor lithography apparatus, an optical metrology inspection tool, or an e-beam inspection tool.
40. The method of any of the previous clauses, wherein the object holder comprises a reticle stage chuck or a wafer stage chuck of a lithography apparatus.
41. The method of any of the previous clauses, wherein the object comprises a reticle or a semiconductor wafer, or wafer table.
42. The method of any of the previous clauses, wherein the second portion of the manipulator is oriented substantially parallel to a scan direction of the motion control system.
43. The method of any of the previous clauses, wherein the second portion of the manipulator is oriented substantially perpendicular to a scan direction of the motion control system.
44. The method of any of the previous clauses, wherein the second portion of the manipulator comprises a hinge and a pivot configured to translate linear motion of the second portion of the manipulator oriented substantially perpendicular to the scan direction into linear motion substantially parallel to the scan direction.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet) and/or DUV lithography that is capable of producing a 193 nm wavelength with the use of an ArF laser, and even a 157 nm wavelength with the use of a Fluorine laser, 248 nm wavelength radiation, and/or other radiation. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments. For example, the inspection system, and the associated software may comprise separate embodiments, and/or these features may be used together in the same embodiment.

The descriptions above are intended to be illustrative, not limiting. Thus, it will be apparent to one skilled in the art that modifications may be made as described without departing from the scope of the claims set out below.

1. A motion control system, comprising:
an object holder configured to hold and move an object;
a long stroke stage with an actuator;
a short stroke stage with an actuator configured to cause the object holder to move with relatively shorter strokes than those of the long stroke stage; and
a manipulator comprising a first portion coupled to the short stroke stage and a second portion coupled to the long stroke stage,
wherein the first portion is configured to support the object held by the object holder to keep the object in an intended position relative to a reference while the object holder moves, and the second portion is configured to interact with the first portion to cause the first portion to support the object.

2. The system of claim 1, wherein:
the reference comprises the object holder;
the support of the object by the first portion comprises application of a force against the object to keep the object in the intended position;
and/or
the interaction of the second portion with the first portion comprises transmission of force from the second portion to the first portion such that the first portion pushes against the object.

3. The system of claim 1, wherein:
the first portion is passive, comprising a pusher with a tip, a pivot, one or more guides, and/or a part of an actuator; and/or
the manipulator comprises a tuned mass damper configured to suppress any unwanted vibrations coming from the pusher.

4. The system of claim 1, wherein the second portion is active, comprising electrical and/or magnetic components including a coil configured to cause the second portion and the first portion to move.

5. The system of claim 1, further comprising one or more processors operatively coupled to the short stroke stage, the long stroke stage, and the manipulator, the one or more processors configured to provide a feedforward signal to the short stroke stage, the long stroke stage, and the manipulator for the object holder, the feedforward signal determined based on a desired setpoint trajectory, and/or based on calibrated and/or calculated corrections.

6. The system of claim 1, wherein:
movement of the object holder comprises acceleration of the object holder;
the object holder comprises a stage in a semiconductor lithography apparatus, an optical metrology inspection tool, or an e-beam inspection tool;
the object holder comprises a reticle stage chuck or a wafer stage chuck of a lithography apparatus; or
the object comprises a reticle or a semiconductor wafer, or wafer table.

7. The system of claim 1, wherein:
the second portion of the manipulator is oriented substantially parallel to a scan direction of the motion control system or the second portion of the manipulator is oriented substantially perpendicular to a scan direction of the motion control system.

8. A motion control method, comprising:
holding and moving an object with an object holder;
causing, with a short stroke stage having an actuator, the object holder to move;
following, with a long stroke stage having an actuator, wherein the short stage moves with relatively shorter strokes than the long stroke stage;
supporting, with a first portion of a manipulator that is coupled to the short stroke stage, the object held by the object holder to keep the object in an intended position relative to a reference while the object holder moves; and
interacting, with a second portion of the manipulator coupled to the long stroke stage, with the first portion to cause the first portion to support the object.

9. The method of claim 8, wherein:
the reference comprises the object holder;
the supporting the object comprises applying a force against the object to keep the object in the intended position;
and/or
the interacting with the first portion comprises transmitting force from the second portion to the first portion such that the first portion pushes against the object.

10. The method of claim 8, wherein:
the first portion is passive, comprising a pusher with a tip, a pivot, one or more guides, and/or part of an actuator; and/or
the manipulator comprises a tuned mass damper configured to suppress any unwanted vibrations coming from the pusher.

11. The method of claim 8, wherein:
the second portion is active, comprising electrical and/or magnetic components including a coil configured to cause the second portion and the first portion to move;
the first and second portions of the manipulator combine to form a zero stiffness stage, such that disturbance forces from the long stroke stage are not passed to the short stroke stage via the manipulator; and/or
the first and second portions of the manipulator combine to form a Lorentz actuator stage, with a magnet and a coil forming the second portion of the Lorentz actuator stage and being coupled to the long stroke stage, away from the first portion and the object.

12. The method of claim 8, further comprising:
providing, with one or more processors operatively coupled to the short stroke stage, the long stroke stage, and the manipulator, a feedforward signal to the short stroke stage, the long stroke stage, and the manipulator for the object holder, the feedforward signal determined based on a desired setpoint trajectory, and/or based on calibrated and/or calculated corrections; and/or
generating, with a force sensor, one or more output signals conveying information related to the force applied against the object, and controlling, with the one or more processors, the short stroke stage, the long stroke stage, and/or the manipulator based on the one or more output signals.

13. The method of claim 8, wherein:
movement of the object holder comprises acceleration of the object holder;
the object holder comprises a stage in a semiconductor lithography apparatus, an optical metrology inspection tool, or an e-beam inspection tool;
the object holder comprises a reticle stage chuck or a wafer stage chuck of a lithography apparatus; or
the object comprises a reticle or a semiconductor wafer, or wafer table.

14. The method of claim 8, wherein:
the second portion of the manipulator is oriented substantially parallel to a scan direction or the second portion of the manipulator is oriented substantially perpendicular to a scan direction; and/or
the second portion of the manipulator comprises a hinge and a pivot configured to translate linear motion of the second portion of the manipulator oriented substantially perpendicular to a scan direction into linear motion substantially parallel to the scan direction.

15. A lithography apparatus comprising:
the motion control system of claim 1; and
a support structure configured to hold a patterning device configured to provide a pattern for transfer to the object.

16. A metrology or inspection tool, comprising:
the motion control system of claim 1; and
a detector configured to inspect or measure the object.

17. The system of claim 1, wherein the second portion of the manipulator comprises a hinge and a pivot configured to translate linear motion of the second portion of the manipulator oriented substantially perpendicular to a scan direction of the motion control system into linear motion substantially parallel to the scan direction.

18. The system of claim 1, further comprising a force sensor configured to generate one or more output signals conveying information related to the force applied against the object, and one or more processors configured to control the short stroke stage, the long stroke stage, and/or the manipulator based on the one or more output signals.

19. The system of claim 1, wherein the first and second portions of the manipulator combine to form a Lorentz actuator stage, with a magnet and a coil forming the second portion of the Lorentz actuator stage and being coupled to the long stroke stage, away from the first portion and the object.

20. The system of claim 1, wherein the first and second portions of the manipulator combine to form a zero stiffness stage, such that disturbance forces from the long stroke stage are not passed to the short stroke stage via the manipulator.
